(19) United States
(12) Patent Application Publication
(10) Pub. No.: US 2026/0371696 A1
(43) Pub. Date: Nov. 19, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Jia LIU, Yokohama Kanagawa (JP); Eitaro MIYAKE, Tachikawa Tokyo (JP); Shun TAKEDA, Yokohama Kanagawa (JP)

(21) Appl. No.: 19/476,084

(22) PCT Filed: Feb. 21, 2024
(86) PCT No.: PCT/JP2024/006391

§ 371 Date: Oct. 16, 2025

(30) Foreign Application Priority Data
Sep. 14, 2023 (JP) 2023-149435

(51) Int. Cl. H10D 80/20; H10W 70/60; H10W 74/10; H10W 90/20

(52) U.S. Cl. CPC H10D 80/251; H10W 70/614; H10W 74/114; H10W 90/20

(57) ABSTRACT

According to the embodiment, a semiconductor device includes a first conductor exposed on a first surface of a package, a first and a second transistors each provided in the package and coupled to the first conductor, an insulating substrate, a second and a third conductors each exposed from a second surface of the package and provided on a third surface of the insulating substrate, a first interconnect layer embedded in the insulating substrate and coupled to the second conductor, a fourth conductor coupled to the first transistor and the third conductor, a fifth conductor coupled to the second transistor and the third conductor, a sixth conductor coupled to a gate of the first transistor and the second conductor, and a seventh conductor provided on a fourth surface of the insulating substrate and coupled to a gate of the second transistor and the first interconnect layer.

### FIELD

Embodiments described herein relate generally to a semiconductor device.

### BACKGROUND

A power module has been known as a semiconductor device that achieves high power output. The power module is configured as a single package in which a plurality of power semiconductors are integrated.

### CITATION LIST

### Patent Literature

Patent Literature 1: Jpn. Pat. Appln. KOKAI Publication No. 2022-165445
Patent Literature 2: U.S. Patent Application Publication No. 2013/0258628

### SUMMARY

### Technical Problem

According to an embodiment of the present invention, a semiconductor device capable of suppressing oscillation in the device is provided.

### Solution to Problem

A semiconductor device according to the embodiment includes a first conductor exposed on a first surface of a package, a first transistor provided in the package and including a drain coupled to the first conductor, a second transistor provided in the package and including a drain coupled to the first conductor, an insulating substrate, a second conductor exposed from a second surface facing the first surface of the package and provided on a third surface of the insulating substrate, a third conductor exposed from the second surface of the package and provided on the third surface of the insulating substrate to be spaced apart from the second conductor, a first interconnect layer embedded in the insulating substrate and coupled to the second conductor, a fourth conductor provided on a fourth surface facing the third surface of the insulating substrate and coupled to a source of the first transistor and the third conductor, a fifth conductor provided on the fourth surface of the insulating substrate and coupled to a source of the second transistor and the third conductor, a sixth conductor provided on the fourth surface of the insulating substrate and coupled to a gate of the first transistor and the second conductor, and a seventh conductor provided on the fourth surface of the insulating substrate and coupled to a gate of the second transistor and the first interconnect layer.

### BRIEF DESCRIPTION OF THE DRAWINGS

FIG. 1 is a circuit diagram showing an example of a circuit configuration of a semiconductor device according to an embodiment.

FIG. 2 is a plan view of a package upper surface of the semiconductor device according to the embodiment.

FIG. 3 is a plan view of a package lower surface of the semiconductor device according to the embodiment.

FIG. 4 is a cross-sectional view of the semiconductor device taken along line A1-A2 in FIGS. 2 and 3.

FIG. 5 is a plan view of a package upper surface of a semiconductor device according to a first modification of the embodiment.

FIG. 6 is a circuit diagram showing a circuit configuration of a semiconductor device according to a second modification of the embodiment.

FIG. 7 is a cross-sectional view of a semiconductor device according to a third modification of the embodiment.

FIG. 8 is a cross-sectional view of a semiconductor device according to a fourth modification of the embodiment.

### DETAILED DESCRIPTION

Hereinafter, embodiments will be explained with reference to the accompanying drawings. In the description below, structural components having similar functions and configurations will be denoted by the same reference symbols. If structural components indicated by the same reference symbols are distinguished, the reference symbols are accompanied by additional symbols. Such additional symbols may be omitted when differentiation is not needed for the structural components. The additional symbols include not only subscripts or superscripts, but also, for example, lowercase alphabetical characters following the reference symbols, or indices representing array, etc.

A semiconductor device according to an embodiment is a power module. The semiconductor device is applied to, for example, a power conversion device for a railway vehicle, an industrial device for a renewable energy power generation system, or the like.

### 1. Circuit Configuration of Semiconductor Device

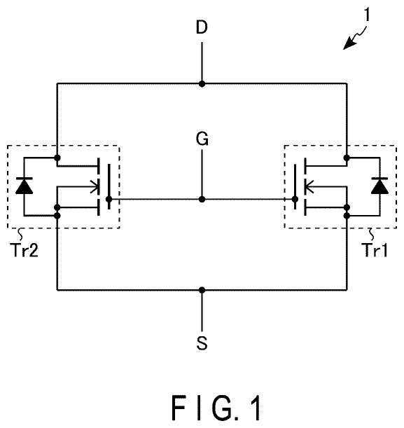

First, with reference to FIG. 1, an example of a circuit configuration of a semiconductor device 1 will be described. FIG. 1 is a circuit diagram showing an example of a circuit configuration of the semiconductor device 1.

As shown in FIG. 1, the semiconductor device 1 includes a plurality of transistors Tr coupled in parallel. In the example shown in FIG. 1, the semiconductor device 1 includes two transistors Tr1 and Tr2 coupled in parallel. The number of transistors Tr coupled in parallel may be three or more.

The transistors Tr1 and Tr2 are, for example, n-channel metal oxide semiconductor (MOS) transistors. A substrate on which the transistor Tr is formed may be a Si substrate or a Sic substrate. Hereinafter, a case where the substrate is Sic will be described.

Respective drains of the transistors Tr1 and Tr2 are coupled in common to a drain terminal D. For example, a positive voltage is applied to the drain terminal D from the outside.

Respective gates of the transistors Tr1 and Tr2 are coupled in common to a gate terminal G. A gate signal (voltage) for controlling the transistors Tr1 and Tr2 is applied to the gate terminal G. A parasitic inductance (also referred to as a “gate inductance”) is generated in a gate interconnect that couples the gate of the transistor Tr1 and the gate of the transistor Tr2.

Respective sources of the transistors Tr1 and Tr2 are coupled in common to a source terminal S. For example, a voltage lower than that applied to the drain terminal D is applied to the source terminal S. A parasitic inductance (also referred to as a “source inductance”) is generated in a source interconnect that couples the source of the transistor Tr1 and the source of the transistor Tr2.

### 2. Configuration of Semiconductor Device

### 2.1 Planar Configuration of Semiconductor Device

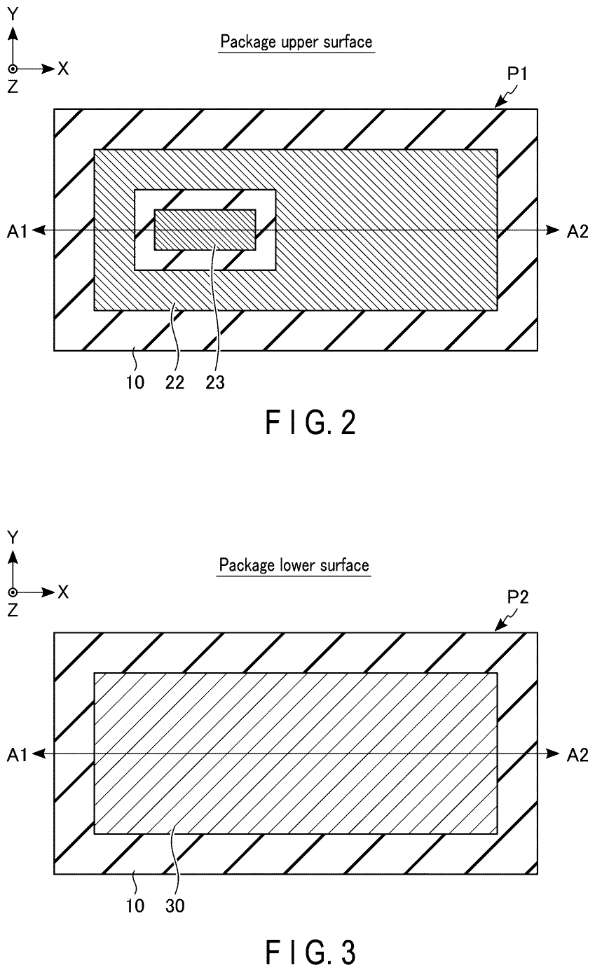

First, with reference to FIGS. 2 and 3, an example of a planar configuration of the semiconductor device 1 will be described. FIG. 2 is a plan view of a package upper surface Pl of the semiconductor device 1. FIG. 3 is a plan view of a package lower surface P2 of the semiconductor device 1. In the following description, a mounting surface to be bonded to a printed circuit board when the semiconductor device 1 is surface mounted on the printed circuit board or the like will be referred to as the “package lower surface P2”. The surface opposite to the package lower surface P2 of the semiconductor device 1 will be referred to as the “package upper surface P1”. In the example of FIGS. 2 and 3, a plane along the package upper surface P1 and the package lower surface P2 is denoted as an XY plane. A direction intersecting the XY plane is denoted as a Z direction.

As shown in FIGS. 2 and 3, a mold resin 10 and conductors 22, 23, and 30 are exposed on the package surface of the semiconductor device 1.

The mold resin 10 seals the semiconductor device 1. The mold resin 10 maintains insulation and arrangement among semiconductor chips (not shown) and the conductors 22, 23, and 30 in the semiconductor device 1 in a stable manner. For the mold resin 10, for example, an epoxy resin is used. The mold resin 10 may contain a filler such as silicon oxide.

The conductors 22, 23, and 30 are made of a conductive material, and contain, for example, copper (Cu). The surface of each conductor exposed from the mold resin 10 (hereinafter referred to as an “exposed surface”) may be covered with tin (Sn), solder, or the like, or may not be covered. The exposed surfaces of the conductors 22, 23, and 30 may function as a heatsink of the semiconductor device 1. FIGS. 2 and 3 illustrate a structure in which each conductor (lead terminal) does not protrude from the mold resin 10 (i. e., a package) as in a dual flatpack non-leaded (DFN), but the structure is not limited thereto. Each conductor may protrude from the mold resin 10. The shape of each conductor is arbitrary.

The conductors 22 and 23 are exposed on the package upper surface P1. For example, the conductor 22 functions as the source terminal S. The conductor 23 functions as the gate terminal G. The exposed surfaces of the conductors 22 and 23 are electrically coupled to a printed circuit board or the like via solder or the like.

The conductor 30 is exposed on the package lower surface P2. For example, the conductor 30 functions as the drain terminal D. For example, the exposed surface of the conductor 30 is electrically coupled to a printed circuit board or the like via solder or the like.

### 2.2 Cross-sectional Configuration of Semiconductor Device

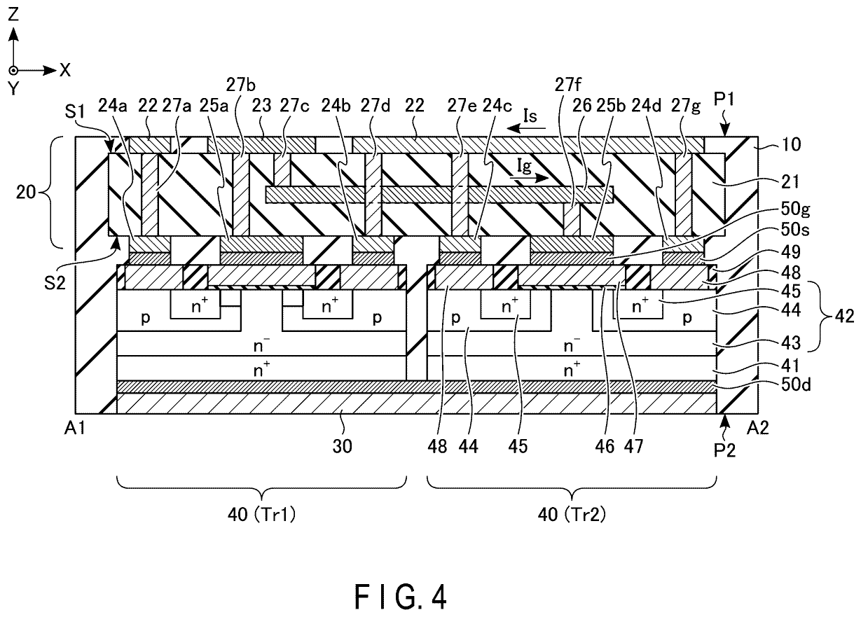

Next, with reference to FIG. 4, an example of a cross-sectional configuration of the semiconductor device 1 will be described. FIG. 4 is a cross-sectional view of the semiconductor device 1 taken along the line A1-A2 in FIGS. 2 and 3. In the following description, a direction in which two semiconductor chips 40 are disposed side by side on the XY plane is defined as an X direction. A direction intersecting the X direction is defined as a Y direction.

As shown in FIG. 4, the semiconductor device 1 includes a mold resin 10, an interconnect substrate 20, a conductor 30, two semiconductor chips 40, and mount materials 50d, 50g, and 50s.

The lower surface of the conductor 30 is exposed on the package lower surface P2. The conductor 30 functions as the drain terminal D. The two semiconductor chips 40 are bonded to the upper surface of the conductor 30 via the mount material 50g. That is, the two semiconductor chips 40 are provided inside the package (mold resin 10).

The two semiconductor chips 40 are the transistors Tr1 and Tr2 described with reference to FIG. 1. The semiconductor chip 40 includes an SiC substrate 41, an epitaxial layer 42, a gate insulating layer 46, a gate electrode 47, a source electrode 48, and a passivation film 49.

The SiC substrate 41 is an n⁺-type substrate. The SiC substrate 41 functions as a drain region. The lower surface of the SiC substrate 41 is bonded to the upper surface of the conductor 30 via the mount material 50g. That is, the lower surface of the SiC substrate 41 is electrically coupled to the conductor 30 (drain terminal D) as a drain electrode. A drain electrode may be separately provided so as to be in contact with the lower surface of the SiC substrate 41. In the example shown in FIG. 4, the two semiconductor chips 40 disposed side by side in the X direction are bonded to the upper surface of the conductor 30 via the mount material 50g.

The epitaxial layer 42 is provided on the upper surface of the SiC substrate 41. An n⁻-type drift region 43, a p-type body region 44, and an n⁺-type source region 45 are provided inside the epitaxial layer 42.

The drift region 43 is provided on the upper surface of the SiC substrate 41, that is, the drain region.

Two p-type body regions 44 are provided in the vicinity of the surface (upper surface) of the drift region 43.

The source region 45 is provided in the vicinity of the surface of the p-type body region 44. For the source region 45, the p-type body region 44 surrounds the source region 45.

The gate insulating layer 46 is provided on the upper surface of the epitaxial layer 42. The lower surface of the gate insulating layer 46 is in contact with parts of the two source regions 45, parts of the two p-type body regions 44, and the drift region 43 between the two p-type body regions 44. For example, between the two source regions 45, a channel of the transistor Tr is formed in the vicinity of the surfaces of the p-type body regions 44 in contact with the gate insulating layer 46. The gate insulating layer 46 is made of an insulating material.

The gate electrode 47 is provided on the upper surface of the gate insulating layer 46. The gate electrode 47 is made of a conductive material.

The source electrodes 48 are respectively provided on the two p-type body regions. More specifically, the source electrode 48 is provided on the upper surfaces of a part of the source region 45 and a part of the p-type body region 44. The source electrode 48 is made of a conductive material. For example, the gate electrode 47 is provided between the two source electrodes 48 in the X direction.

The passivation film 49 is provided so as to surround the gate electrode 47 and the source electrode 48. The passivation film 49 physically and electrically separates the gate electrode 47 and the source electrode 48 from each other. The passivation film 49 is made of, for example, a resin material such as polyimide.

The interconnect substrate 20 is provided above the semiconductor chips 40. That is, the semiconductor chips 40 are provided between the conductor 30 and the The gate electrode 47 is electrically coupled to the interconnect substrate 20 via the mount material 50g. The source electrode 48 is electrically coupled to the interconnect substrate 20 via the mount material 50s.

The mount materials 50d, 50g, and 50s are made of a conductive material. For example, solder is used for the mount materials 50d, 50g, and 50s. Note that instead of the solder, a sintered material that is not easily melted (e.g., any of copper, silver, lead, a tin-copper compound, a tin-silver compound, or a tin-nickel compound) may be used. In this case, a pressure-sintered material having excellent pressure resistance may be used.

Next, an internal configuration of the interconnect substrate 20 will be described. The interconnect substrate 20 is a multilayer interconnect substrate having a plurality of conductors (interconnect layers) provided on both surfaces and inside. The interconnect substrate 20 includes an insulating substrate 21, a conductor 22, a conductor 23, conductors 24a to 24d, conductors 25a and 25b, a gate interconnect 26, and contact plugs 27a to 27g. The conductor 22, the conductor 23, the conductors 24a to 24d, the conductors 25a and 25b, the gate interconnect 26, and the contact plugs 27a to 27g are made of a conductive material, and contain, for example, copper.

The insulating substrate 21 is made of an insulating material. The insulating substrate 21 may be, for example, ceramic or may contain a thermosetting resin.

The conductor 22 is provided on an upper surface S1 of the insulating substrate 21. An upper surface of the conductor 22 is exposed on the package upper surface Pl and functions as the source interconnect and the source terminal S.

The conductor 23 is provided on the upper surface S1 of the insulating substrate 21 so as to be spaced apart from the conductor 22. An upper surface of the conductor 23 is exposed on the package upper surface P1 and functions as the gate terminal G.

The conductors 24a to 24d and the conductors 25a and 25b are provided on a lower surface S2 of the insulating substrate 21.

The respective conductors 24a to 24d are coupled to the source electrodes 48 of the semiconductor chips 40 via the mount materials 50s. For example, the conductors 24a and 24b are respectively coupled to the two source electrodes 48 of the semiconductor chip 40 (transistor Tr1). The conductors 24c and 24d are respectively coupled to the two source electrodes 48 of the semiconductor chip 40 (transistor Tr2).

The respective conductors 25a and 25b are coupled to the gate electrodes 47 of the semiconductor chips 40 via the mount materials 50g. For example, the conductor 25a is coupled to the gate electrode 47 of the semiconductor chip 40 (transistor Tr1). The conductor 25b is coupled to the gate electrode 47 of the semiconductor chip 40 (transistor Tr2).

The gate interconnect 26 is embedded in the insulating substrate 21. The gate interconnect 26 is disposed between the upper surface S1 and the lower surface S2 of the insulating substrate 21 in the Z direction. The gate interconnect 26 extends on the XY plane. For the gate interconnect 26, an interconnect width, an interconnect thickness, and an interconnect length (interconnect layout) can be set arbitrarily. The gate inductance of the gate interconnect 26 can be adjusted by adjusting the interconnect width, the interconnect thickness, and the interconnect length of the gate interconnect 26.

The gate interconnect 26 is disposed parallel to the conductor 22 in the Z direction.

The contact plugs 27a to 27g are provided in the insulating substrate 21. The contact plugs 27a to 27g extend in the Z direction. One end of the contact plug 27a is coupled to the conductor 22, and the other end is coupled to the conductor 24a. One end of the contact plug 27b is coupled to the conductor 23, and the other end is coupled to the conductor 25a. One end of the contact plug 27c is coupled to the conductor 23, and the other end is coupled to the gate interconnect 26. One end of the contact plug 27d is coupled to the conductor 22, and the other end is coupled to the conductor 24b. One end of the contact plug 27e is coupled to the conductor 22, and the other end is coupled to the conductor 24c. One end of the contact plug 27f is coupled to the gate interconnect 26, and the other end is coupled to the conductor 25b. One end of the contact plug 27g is coupled to the conductor 22, and the other end is coupled to the conductor 24d.

A current flowing through the gate interconnect 26 is denoted by Ig, and a current flowing through the conductor 22 (that is, the source interconnect) is denoted by Is. In the present embodiment, the conductor 22 and the gate interconnect 26 are laid out so that the currents Ig and Is flow in opposite directions. That is, the layout is made so that the gate signal flowing through the gate interconnect 26 and the source signal flowing through the conductor 22 are in phases opposite to each other. This causes the gate inductance to be in the opposite phase to the source inductance. Therefore, the gate inductance is canceled by the mutual inductance of the gate inductance and the source inductance.

With the configuration according to the present embodiment, it is possible to provide a semiconductor device 1 capable of suppressing oscillation in the device.

For example, in a loop between transistors coupled in parallel, when the length of the source interconnect is increased, the source inductance between the transistors is increased, and oscillation is likely to occur at the time of switching. As a countermeasure against the oscillation, it is effective to increase the gate inductance between the transistors. However, when the gate inductance increases, the performance of the semiconductor device is degraded due to substrate variation in transistor switching, a decrease in switching speed, or the like.

In contrast, with the configuration according to the present embodiment, in the semiconductor device 1, the interconnect substrate 20 can be used for coupling the semiconductor chips 40 with the gate terminal G and the source terminal S. By using the interconnect substrate 20, the current paths (interconnect layout) of the gate interconnect and the source interconnect can be optimized. That is, the gate inductance and the source inductance between the semiconductor chips 40 can be adjusted. This can increase the gate inductance. Moreover, the current path of the source interconnect is adjusted to be short, and the area of the interconnect is increased, whereby the source inductance can be reduced.

Furthermore, with the configuration according to the present embodiment, in the semiconductor device 1, it is possible to lay out the conductor 22 (that is, the source interconnect) and the gate interconnect 26 so that the gate current Ig and the source current Is flow in opposite directions in the interconnect substrate 20. This allows the gate inductance to be in the opposite phase to the source inductance. Therefore, the gate inductance can be canceled by the mutual inductance with the source inductance. Therefore, it is possible to suppress a decrease in switching speed due to the gate inductance.

Furthermore, with the configuration according to the present embodiment, in the semiconductor device 1, the conductors 22 and 23 provided on the upper surface S1 of the interconnect substrate 20 can be exposed from the package upper surface P1. In addition, in the semiconductor device 1, the conductor 30 can be exposed from the package lower surface P2. Thus, in the semiconductor device 1, the conductors (metal materials) having excellent thermal conductivity can be exposed from both surfaces of the package. That is, in the semiconductor device 1, it is possible to dissipate heat from both surfaces of the package. Therefore, heat dissipation of the semiconductor device 1 can be improved.

### 3. Modifications

The present invention is not limited to the above-described embodiment, and various modifications can be applied. Three modifications will be described below. In the following modifications, differences from the embodiment will mainly be described.

### 3.1 First Modification

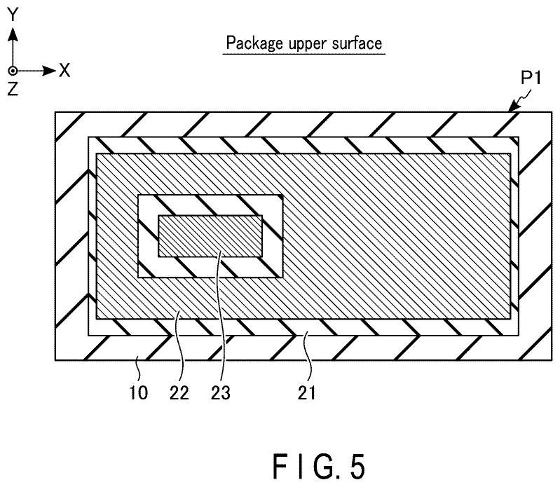

With reference to FIG. 5, a first modification will be described. FIG. 5 is a plan view of the package upper surface P1 of the semiconductor device 1.

As shown in FIG. 5, the insulating substrate 21 may be exposed on the package upper surface Pl of the semiconductor device 1.

### 3.2 Second Modification

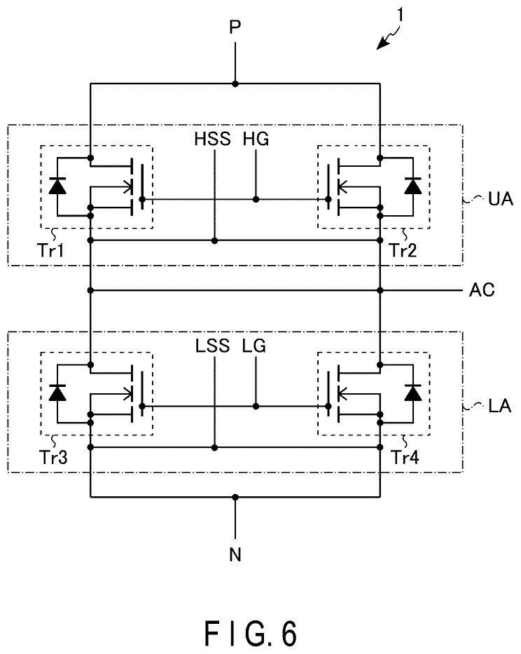

With reference to FIG. 6, a second modification will be described. FIG. 6 is a circuit diagram showing a circuit configuration of the semiconductor device 1. The semiconductor device 1 may have the circuit configuration shown in FIG. 6.

As shown in FIG. 6, for example, the semiconductor device 1 includes an upper arm portion UA including a plurality of transistors coupled in parallel, and a lower arm portion LA including a plurality of transistors coupled in parallel. The upper arm portion UA and the lower arm portion LA are coupled in series. Each arm portion corresponds to the circuit configuration described with reference to FIG. 1.

The upper arm portion UA includes transistors Tr1 and Tr2. The transistor Tr1 and the transistor Tr2 are coupled in parallel.

The lower arm portion LA includes transistors Tr3 and Tr4. The transistor Tr3 and the transistor Tr4 are coupled in parallel.

The transistors Tr1, Tr2, Tr3, and Tr4 are, for example, n-channel MOS transistors.

Respective drains of the transistors Tr1 and Tr2 are coupled in common to a positive electrode terminal P. A positive voltage is applied to the positive electrode terminal P from the outside. Respective gates of the transistors Tr1 and Tr2 are coupled in common to an upper gate terminal HG via an upper gate interconnect. Respective sources of the transistors Tr1 and Tr2 are coupled in common to an upper source sense terminal HSS via an upper source sense interconnect. The upper source sense terminal HSS is used to sense (monitor) a source voltage of the transistors Tr1 and Tr2. The respective sources of the transistors Tr1 and Tr2 are coupled in common to an output terminal AC and drains of the transistors Tr3 and Tr4.

Respective gates of the transistors Tr3 and Tr4 are coupled in common to a lower gate terminal LG via a lower gate interconnect. Respective sources of the transistors Tr3 and Tr4 are coupled in common to a lower source sense terminal LSS via a lower source sense interconnect. The lower source sense terminal LSS is used to sense (monitor) a source voltage of the transistors Tr3 and Tr4. The respective sources of the transistors Tr3 and Tr4 are coupled in common to a negative electrode terminal N. A voltage lower than that applied to the positive electrode terminal P is applied to the negative electrode terminal N.

### 3.3 Third Modification

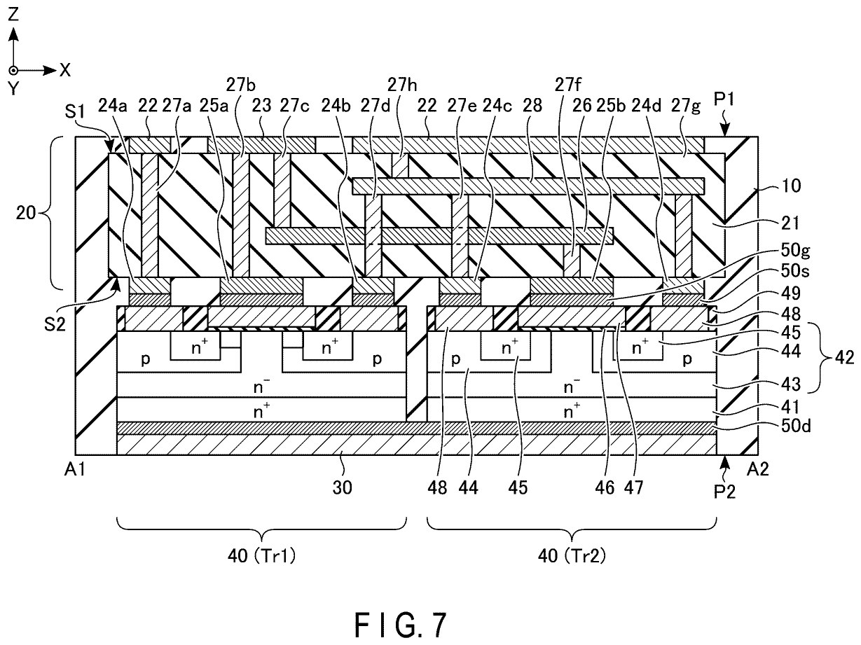

With reference to FIG. 7, a third modification will be described. FIG. 7 is a cross-sectional view of the semiconductor device 1.

As shown in FIG. 7, the interconnect substrate 20 may further include a source interconnect 28 embedded in the insulating substrate 21. For example, the source interconnect 28 is disposed between the upper surface S1 of the insulating substrate 21 and the upper surface of the gate interconnect 26 in the Z direction. The source interconnect 28 extends on the XY plane. The source interconnect 28 is disposed parallel to the gate interconnect 26 in the Z direction. The source interconnect 28 is coupled to the conductor 22 via the contact plug 27h.

### 3.4 Fourth Modification

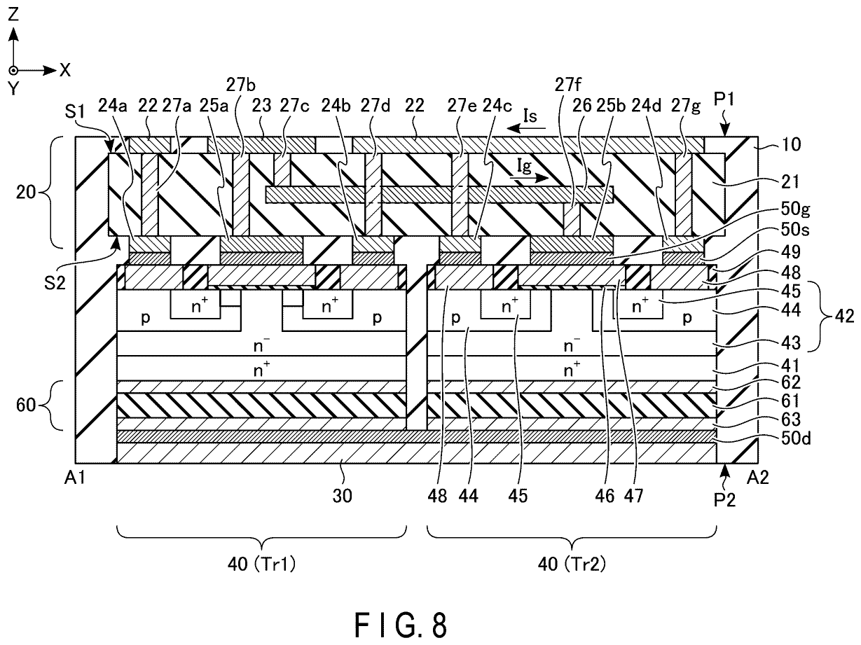

With reference to FIG. 8, a fourth modification will be described. FIG. 8 is a cross-sectional view of the semiconductor device 1.

As shown in FIG. 8, an interconnect substrate 60 may be provided between the semiconductor chip 40 and the conductor 30. The interconnect substrate 60 is a interconnect substrate having a plurality of conductors provided on both surfaces. The interconnect substrate 60 includes an insulating substrate 61, a conductor 62, and a conductor 63. The insulating substrate 61 is made of an insulating material. The conductor 62 and the conductor 63 are made of a conductive material, and contain, for example, copper.

The conductor 62 is provided on the upper surface of the insulating substrate 61 and is coupled to the sic substrate (drain region) of the semiconductor chip 40.

The conductor 63 is provided on the lower surface of the insulating substrate 61 and is coupled to the conductor 30 via the mount material 50d. The conductors 62 and 63 are electrically coupled to each other by a contact plug (not shown).

The term “couple” in the above-described embodiments also includes the state of indirect connection or coupling via a transistor, a resistor, etc. or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductor exposed on a first surface of a package;
a first transistor provided in the package and including a drain coupled to the first conductor;
a second transistor provided in the package and including a drain coupled to the first conductor;
an insulating substrate;
a second conductor exposed from a second surface of the package and provided on a third surface of the insulating substrate, the second surface facing the first surface;
a third conductor exposed from the second surface of the package and provided on the third surface of the insulating substrate to be spaced apart from the second conductor;
a first interconnect layer embedded in the insulating substrate and coupled to the second conductor;
a fourth conductor provided on a fourth surface of the insulating substrate and coupled to a source of the first transistor and the third conductor, the fourth surface facing the third surface;
a fifth conductor provided on the fourth surface of the insulating substrate and coupled to a source of the second transistor and the third conductor;
a sixth conductor provided on the fourth surface of the insulating substrate and coupled to a gate of the first transistor and the second conductor; and
a seventh conductor provided on the fourth surface of the insulating substrate and coupled to a gate of the second transistor and the first interconnect layer.

2. The semiconductor device according to claim 1,
wherein the third conductor and the first interconnect layer are disposed in parallel.

3. The semiconductor device according to claim 1,
wherein a first signal applied to the third conductor and a second signal applied to the first interconnect layer are in opposite phases to each other.

4. The semiconductor device according to claim 1,
wherein the first transistor and the second transistor are disposed between the first conductor and the insulating substrate.
